(19) United States
(12) Patent Application Publication
(10) Pub. No.: US 2025/0202465 A1
(43) Pub. Date: Jun. 19, 2025

(54) Systems, Methods, and Devices of Tri-State Inverters

(71) Applicant: Arm Limited, Cambridge (GB)

(72) Inventors: Franck Gregory Ciotti, Nice (FR); Ei Mehdi Boujamaa, Valbonne (FR); Rainer Herberholz, Great Abington (GB)

(21) Appl. No.: 18/985,249

(22) Filed: Dec. 18, 2024

(30) Foreign Application Priority Data
Dec. 18, 2023 (GB) 2319372.5

(51) Int. Cl. H03K 5/131; H03K 5/00; H03K 5/14; H03K 19/094; H03K 19/0948

(52) U.S. Cl. CPC H03K 5/131; H03K 19/09429; H03K 19/0948; H03K 2005/00071; H03K 5/14

(57) ABSTRACT

According to one implementation, a circuit includes a first digital gate (108A) and a timing offset circuit portion (238) coupled to the first digital gate (108A) that includes one or more tri-state inverters (202A . . . 202N) where a capacitance at an output of the first digital gate (108A) is based on a quantity of enabled tri-state inverters of the one or more tri-state inverters (202A-202N).

### FIELD

The present disclosure is generally related to the systems, methods, and devices of one or more tri-state inverters.

### DESCRIPTION

This section is intended to provide information relevant to understanding various technologies described herein. As the section's heading implies, this is a discussion of related art that in no way implies that the discussion is prior art. Generally, related art may or may not be considered prior art. Any statement in this section should be read in this light, and not as admission of prior art.

A droop detector is a component used in power supply systems, especially in voltage regulators, to monitor and detect changes in output voltage levels, particularly during load variations or transient conditions. In a power supply, droop refers to the reduction in output voltage that occurs when there is an increase in load current. The droop detector's function is to detect and measure this droop in the output voltage and provide feedback to a control system, allowing adjustments to be made to maintain stable output voltage levels, especially under varying load conditions.

### SUMMARY

According to one implementation of the present disclosure, a circuit includes one or more tri-state inverters where each enabled tri-state inverter of the one or more tri-state inverters is configured to provide a respective delay adjustment of a signal waveform.

According to another implementation of the present disclosure, a method includes determining a first gate capacitance at a node between first and second digital gates coupled to one or more tri-state inverters; activating at least one of the one or more tri-state inverters; and determining a second gate capacitance at the node, wherein a difference between first and second gate capacitances corresponds to a delay adjustment of a signal waveform.

According to another implementation of the present disclosure, a circuit includes first digital gate, and a timing offset circuit portion coupled to the first digital gate, that includes one or more tri-state inverters where a capacitance at an output of the first digital gate is based on a quantity of enabled tri-state inverters of the one or more tri-state inverters.

The above-referenced summary section is provided to introduce a selection of concepts in a simplified form that are further described below in the detailed description section. Additional concepts and various other implementations are also described in the detailed description. The summary is not intended to identify key features or essential features of the claimed subject matter, nor is it intended to be used to limit the scope of the claimed subject matter, nor is it intended to limit the number of inventions described herein. Furthermore, the claimed subject matter is not limited to implementations that solve any or all disadvantages noted in any part of this disclosure.

### BRIEF DESCRIPTION OF THE DRAWINGS

Implementations of various techniques are described herein with reference to the accompanying drawings. The accompanying drawings illustrate various implementations described herein and are not meant to limit embodiments of various techniques described herein.

FIG. 1A is a diagram in accordance with certain implementations.

FIG. 1B is a diagram in accordance with certain implementations.

FIG. 1C is a graph in accordance with certain implementations.

FIG. 1D is a graph in accordance with certain implementations.

FIG. 1E is a graph in accordance with certain implementations.

FIG. 2A is a diagram in accordance with certain implementations.

FIG. 2B is a graph in accordance with certain implementations.

FIG. 2C is a graph in accordance with certain implementations.

FIG. 2D is a graph in accordance with certain implementations.

FIG. 3A is a diagram in accordance with certain implementations.

FIG. 3B is a waveform diagram of FIG. 3A.

FIG. 3C is a graph in accordance with certain implementations.

FIG. 4 is a block diagram in accordance with implementations of various techniques described herein.

FIG. 5 is a block diagram of a computer system in accordance with implementations of various techniques described herein.

### DETAILED DESCRIPTION

Schemes and techniques relate to the capacity to provide clarity in resolution, for example, for a voltage droop detector. Advantageously, inventive fractional offset circuitry, as described herein, provide such clarity in resolution. In certain implementations, a digital driving gate is “loaded” with multiple tri-state inverters that are included in a fractional offset circuit. In some implementations, a slope of an input signal waveform at an output of the digital driving gate is based on a number of enabled (i.e., activated) tri-state inverters. In certain implementations, a relative increase in delay of the input signal waveform is scaled identically (e.g., each slight delay increase provided by each tri-state inverter is approximately identical) by selecting matching VT-types (e.g., where VT-type refers to the threshold voltage characteristics associated with different types or categories of transistors) in the digital driving gate and in the tri-state inverters. According to inventive aspects, matching VT-types in the digital driving gate and in the tri-state inverters enable a single trim of the delay (e.g., higher resolution) across multiple voltages/temperatures.

According to inventive aspects, the input signal waveform can be trimmed with trimmable timing offsets (e.g., each slight delay) smaller than a gate delay. In some implementations, the input signal waveform is trimmed with the trimmable timing offsets without adding resistance to the fractional offset circuit through the tri-state inverters.

According to various implementations, a fractional offset circuit is a component within electronic systems used to create or adjust a voltage or current offset by a fraction of the input signal. The purpose of a fractional offset circuit is to introduce a controlled and precise deviation in the signal level. This deviation is often expressed as a fraction or percentage of the input signal, allowing for fine adjustments without entirely altering the signal's characteristics. Fractional offset circuits are valuable in scenarios where precise adjustments to signal levels are advantageous, such as in sensor calibration, audio processing, or in analog-to-digital converter (ADC) circuits to ensure accurate measurements within a range. In a non-limiting example, a fractional offset circuit might be utilized to calibrate sensor readings by introducing a small, calculated offset to compensate for inaccuracies or environmental factors affecting the sensor's output.

In certain aspects, capacitors in line with a switch are involved in circuits used to create fractional offsets by manipulating the charging and discharging characteristics of the circuit. In combination with other components like resistors or operational amplifiers, capacitors play a role in generating a controlled offset voltage or current. But one problem with such an approach is that a series resistance of the switch would be added onto the capacitors, and such extraneous series resistance can impact the capacity for accuracy and precision in generating the controlled offset voltage or the current. Hence, advantageously, example implementations as described herein, provide for circuit designs that eliminate the requirement for such switch-capacitor designs altogether and, thus, alleviate any related concerns of such usage.

For purposes of this discussion, “higher resolution” means a greater level of detail or clarity. In certain aspects, the least detectable voltage droop is one gate delay shift that corresponds to approximately 2% of Vdd (the supply voltage or the positive power supply terminal) droop (e.g., the difference in the voltage of the gate output compared to the voltage of the gate input). This voltage droop is coarse and there is a desire for a more precise way of measuring the voltage droop. It is advantageous to reduce the least detectable voltage droop from 2% to lower than 1% of Vdd to increase the clarity in resolution in, for example, a voltage droop detector.

In certain aspects, a droop detector detects a voltage droop by means of gate delays. Gate delay refers to the time taken for a digital logic gate to produce an output change in response to a change in an input to the digital logic gate. Gate delay is a characteristic of digital circuits and represents the time delay between an input transition and the corresponding output transition in a logic gate. In digital circuits, logic gates (such as AND gate, OR gate, NOT gate (e.g., inverter), and the like) perform operations based on input signals, producing an output based on the logic function they are designed to implement. Gate delay measures the time taken for the output of the gate to respond to changes in the input signals.

Calibrating a droop detector involves ensuring accuracy in detecting and responding to changes in voltage or frequency within a power system. This calibration process typically involves several steps such as: 1) establishing a baseline to measure and record the baseline voltage and frequency levels within the power system (e.g., by doing so, a reference point may be established for evaluating the droop detector's responses); 2) applying variations to introduce controlled variations in voltage or frequency (e.g., this could involve simulating load changes or deliberately altering the system parameters to observe how the droop detector responds); 3) comparison and adjustment to compare the droop detector's responses to the known variations introduced; 4) optionally adjusting the detector's settings or calibration parameters to ensure the droop detector accurately detects and responds to these changes within the specified tolerances; 5) validating the calibration by repeating tests and confirming that the droop detector consistently performs within the required accuracy levels (e.g., such a step might involve running various scenarios to simulate different operating conditions and ensuring the detector responds appropriately each time).

A tri-state inverter is a digital logic circuit that combines the functionality of a standard inverter with an additional high-impedance (tri-state) output state. This additional state allows the output to assume three different conditions: high, low, or a high-impedance state that effectively disconnects the output from the circuit. In response to a control signal (often referred to as the enable signal) in a state (typically a third logic level, neither high nor low), the output of the inverter enters the high-impedance state. In this state, the output effectively disconnects from the circuit, presenting a high-impedance path. The high-impedance state is usually controlled by an additional control signal. When this control signal is activated, the tri-state inverter enters the high-impedance state. When the control signal is inactive, the inverter operates as a standard inverter, producing an inverted output based on the input signal.

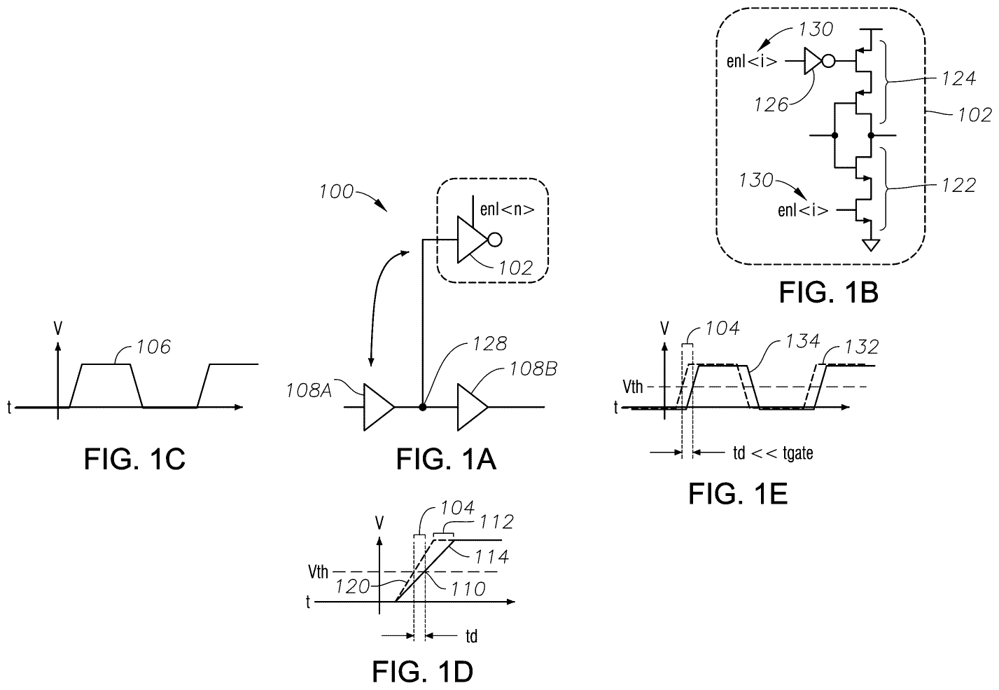

FIG. 1A is a block diagram of a fractional offset circuit 100, in accordance with certain example implementations. FIG. 1B is a schematic diagram of a tri-state inverter 102 for the fractional offset circuit 100, in accordance with certain example implementations. FIG. 1C is a graphical representation of an input signal waveform 106 for the fractional offset circuit 100, in accordance with certain example implementations. FIG. 1D is a graphical representation of a delay adjustment (td) 104 of the fractional offset circuit 100, in accordance with certain example implementations. FIG. 1E is a graphical representation of an output signal for the fractional offset circuit 100, in accordance with certain example implementations.

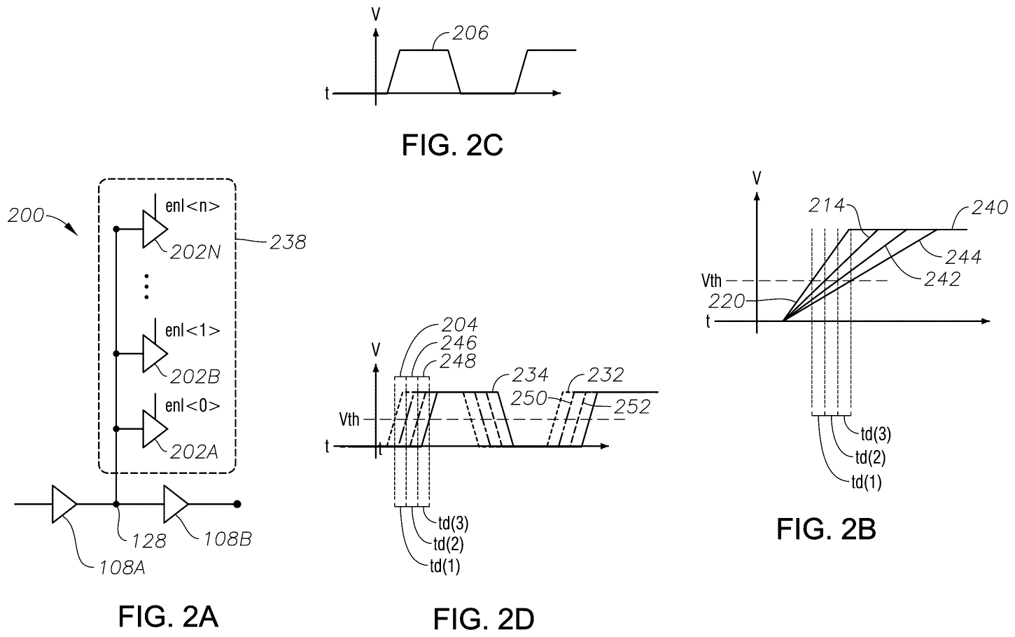

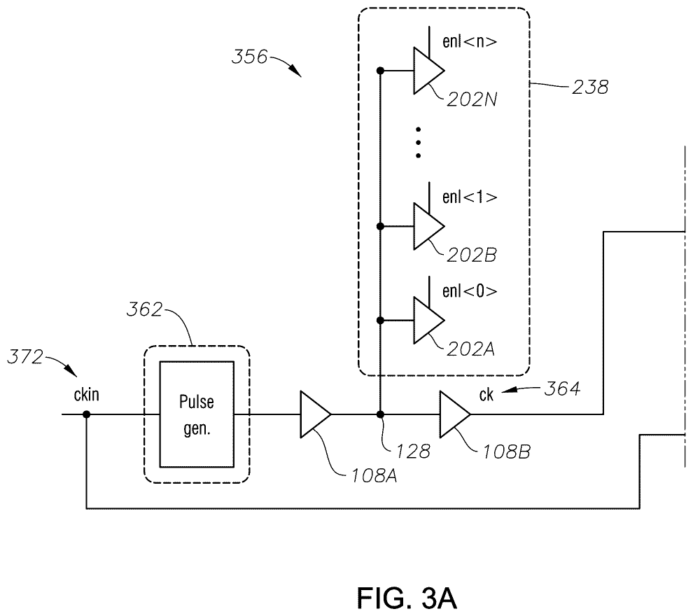

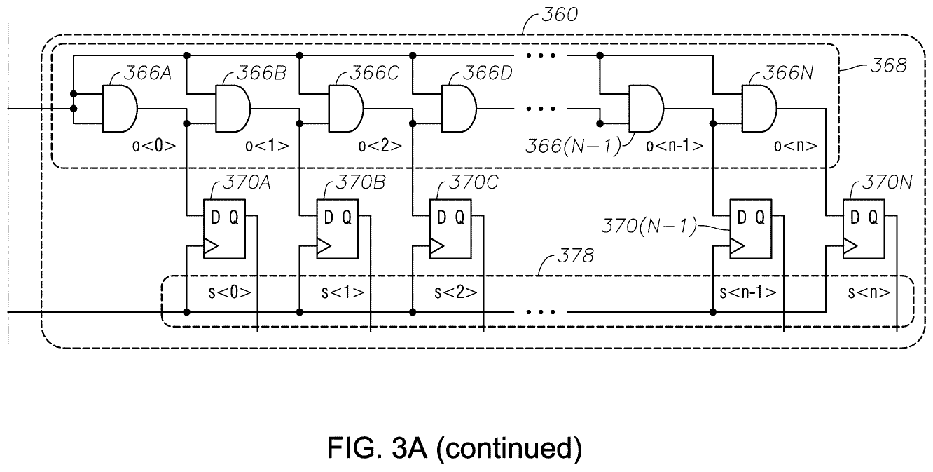

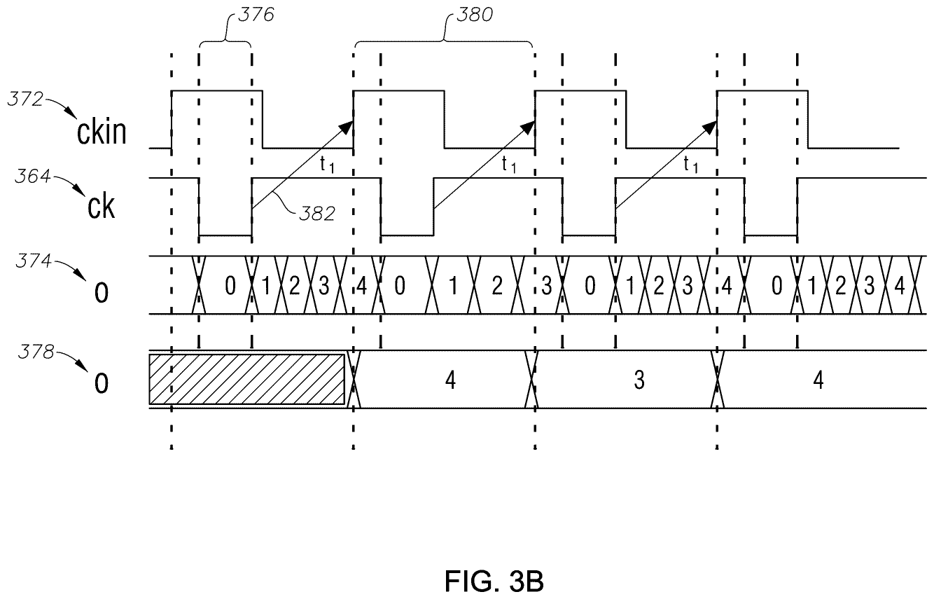

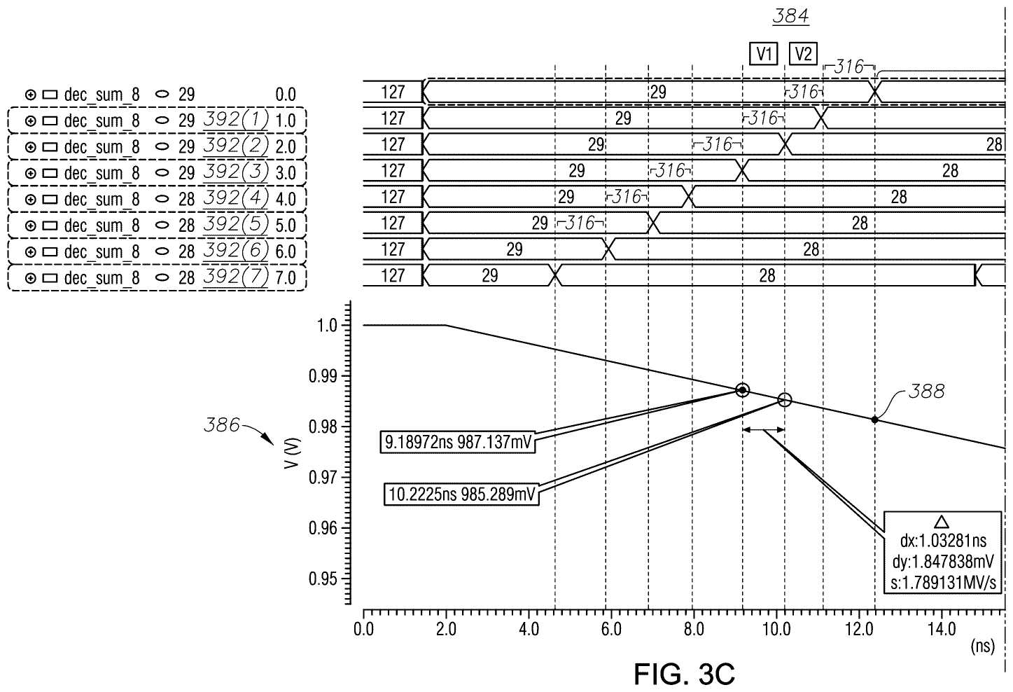

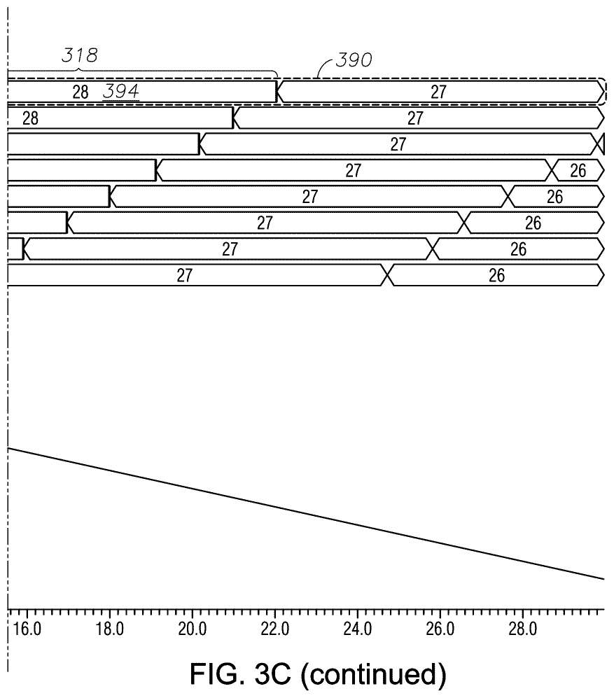

In various cases, fractional offset circuits 100, 200 (FIG. 2A), and droop detector circuit 356 (FIG. 3A) as illustrated in FIGS. 1A, 2A, and 3A may be implemented as a system or a device having various integrated circuit (IC) components that are arranged and coupled together as an assemblage or combination of parts that provide for a physical circuit design and related structures. Further, fractional offset circuits 100, 200 (FIG. 2A), and the droop detector circuit 356 (FIG. 3A) are able to be integrated with computing circuitry and related components on multiple chips, and fractional offset circuits 100, 200 (FIG. 2A), and the droop detector circuit 356 (FIG. 3A) are able to be implemented in embedded systems, e.g., for automotive, electronic, mobile and Internet-of-things (IoT) applications.

As illustrated, in FIGS. 1A-1E, an example the fractional offset circuit 100 includes the tri-state inverter 102 that in response to being enabled (through an enable control signal (e.g., enl<i> 130, enl<n>, where enl<i> 130 can equal enl<n>)), is configured to provide (e.g., generate) a respective (e.g., successive, incremental) delay adjustment (td) 104 of the input signal waveform 106 (e.g., clock signal; CK pulse, voltage signal) from a pulse generator, such as pulse generator 362 (FIG. 3A). The delay adjustment (td) 104 corresponds to a duration less than a gate delay (e.g., td<<tgate), and the gate delay (tgate) corresponds to a delay (e.g., an operation) of a logic gate, such as digital gate 108B, coupled to the tri-state inverter 102. One of ordinary skill in the art understands a gate delay can be the smallest measurable delay of an input signal through a logic gate without departing from the spirit of the various implementations.

The delay adjustment (td) 104 corresponds to a change in a slope 112 of the input signal waveform 106 plotted on a graph of voltage as a function of time. Enabled tri-state inverter, such as the tri-state inverter 102, is configured to provide the delay adjustment (td) 104 (e.g., a step delay to trim the input signal waveform 106 based on a respective different slope, such as the slope 114, of the input signal waveform 106; a delay offset) of the input signal waveform 106. The delay adjustment (td) 104 can be made in incremental (e.g., step) portions 316 (FIG. 3C) (e.g., a fraction, such as ≤⅛th of gate delay 318 (FIG. 3C discussed in greater detail below) of durations less (e.g., much smaller) than a gate delay (e.g., duration). The enabled tri-state inverter, such as the tri-state inverter 102, is configured to provide the delay adjustment (td) 104 of the input signal waveform 106 and the difference between the delay adjustment (td) 104 and the input signal waveform 106 corresponds to a difference between the slope 114 of the enabled tri-state inverter and a slope 120 of the input clock signal 106 plotted on a graph of voltage as a function of time.

The tri-state inverter 102 includes a pair of NMOS transistors 122, a pair of PMOS transistors 124, and an inverter 126. The tri-state inverter 102 is enabled upon the enable control signal (enl<i>) 130 enabling a first PMOS transistor of the pair of PMOS transistors 124 and enabling a first NMOS transistor of the pair of NMOS transistors 122. A node 128 is coupled between a first digital gate 108A and a second digital gate 108B (e.g., first and second buffers), where the tri-state inverter 102 and, at least, the first digital gate 108A include a same VT-type. A capacitance provided by the tri-state inverter 102 at the node 128 corresponds to the respective delay adjustment (td) 104. That is, capacitance at the node 128 provides the delay adjustment (td) 104.

In circuit design, a buffer is an electronic component or a circuit designed to isolate or separate one part of a circuit from another, preventing interference or loading effects between them. Buffers are used to maintain signal integrity and ensure that the output signal closely resembles the input signal. Buffers typically have a voltage gain of approximately 1 (unity gain), meaning they do not amplify the signal but maintain its voltage level and current capabilities. In complex circuits, where signals pass through multiple stages or components, buffers help prevent signal degradation by ensuring that the subsequent stages receive the signal with minimal distortion. While the first digital gate 108A and the second digital gate 108B can be first and second buffers, one of ordinary skill in the art understands that the first digital gate 108A and the second digital gate 108B can be an inverter, a transceiver, a level shifter, a driver circuit, a repeater, or the like without departing from the spirit of the implementations.

In a non-limiting example, transmitted at the input of the first digital gate 108A is the input signal waveform 106, such as from the pulse generator 362 (FIG. 3A). In response to the tri-state inverter 102 not being enabled, the slope 120 is realized, or alternately stated, as the original slope of the input signal waveform 106. As the tri-state inverter 102 is not enabled, there is no capacitive load from the tri-state inverter 102 coupled to the node 128. The slope 114, a slightly decreased slope, is realized at the node 128 in response to the tri-state inverter 102 being enabled (e.g., the lower NMOS transistor of the pair of NMOS transistors 122 is turned on and the upper PMOS transistor of the pair of PMOS transistors 124 is turned on in response to the enable control signal (enl<i>) 130 being at a digital high state (1)).

Continuing with such a non-limiting example, in certain cases, where Vth crosses the slope 114, at a crossing point 110, corresponds to a threshold voltage (Vth) of the second digital gate 108B. There is a small-time delay (e.g., 1 ps) to reach the threshold voltage (Vth) of the second digital gate 108B in comparison to the time the second digital gate 108B reaches the threshold voltage (Vth) with the slope 120. This small-time delay is the delay adjustment (td) 104 that corresponds to a difference in the slope at the second digital gate 108B voltage threshold crossing on the node 128.

As illustrated in FIG. 1E, dashed line 132 represents the input signal waveform 106 in response to the tri-state inverter 102 being disabled and no capacitive load being at the node 128. Solid line 134 represents the input signal waveform 106 in response to the tri-state inverter 102 being enabled and a capacitive load being placed at the node 128 by the enabled tri-state inverter, such as the tri-state inverter 102. The solid line 134 represents the input signal waveform 106 delayed by delay adjustment (td) 104. Thus, a waveform, such as the input signal waveform 106, can be delayed with a delay, such as delay 316 (as illustrated in FIG. 3C), much smaller than a gate delay, such as the gate delay 318 (as illustrated in FIG. 3C), by means of different slopes, such as the slope 114.

Continuing with such a non-limiting example, in certain cases, the slope 114 is realized based on trimming the capacitance on the node 128 through the tri-state inverter 102. In response to the tri-state inverter 102 being disabled, the gate capacitance of the upper NMOS transistor of the pair of NMOS transistors 122 and the lower PMOS transistor of the pair of PMOS transistors 124 is not connected to the node 128. Therefore, a source of the upper NMOS transistor and a source of the lower PMOS transistor are “floating” (e.g., in a floating condition where the component or circuit is electrically isolated and there is no direct connection to a specific voltage level or ground potential). Moreover, the capacitance between a gate and the source on the lower PMOS transistor and a gate and the source on the upper NMOS transistor are also floating. As the source of the upper NMOS transistor and the source of the lower PMOS transistor are floating, the transistors would not capacitively load the node 128.

In certain instances, in response to the tri-state inverter 102 being enabled, the gate capacitance of the upper NMOS transistor of the pair of NMOS transistors 122 and the lower PMOS transistor of the pair of PMOS transistors 124 is realized at the node 128 that “slightly” loads the node 128 with capacitance (e.g., slightly as the capacitance added is a “small” gate capacitance (e.g., the gate-to-source capacitance (Cgs) that typically ranges from a few femtofarads (fF) to hundreds of femtofarads)). Therefore, the slope 114 is slightly “less steep” (e.g., at a decreased angle of inclination from horizontal) or inclined as the slope 120 as the node 128 is slightly capacitively loaded (e.g., a few femtofarads (fF) to hundreds of femtofarads of the tri-state inverter 102). Correspondingly, this capacitive loading at the node 128 delays, by the delay adjustment (td) 104 (e.g., 1 ps), the next digital gate, such as the second digital gate 108B, reaching Vth and this results in a delay of the input signal waveform 106 shown as the solid line 134.

Continuing with such a non-limiting example, in certain cases, for reliable tracking on PVT variations (process, voltage, and temperature), the first digital gate 108A and the tri-state inverter 102 may be configured with the same or approximately the same VT-type. In semiconductor design and manufacturing, achieving accurate and precise tracking on PVT variations is advantageous for ensuring reliable performance and functionality of integrated circuits across different operating conditions. As may be appreciated, reliable tracking implies that the circuit or design maintains consistent performance and functionality despite variations in process parameters, supply voltage levels, and operating temperatures. In addition, such tracking indicates the circuit should operate reliably within specified parameters under different PVT conditions.

Advantageously, inventive fractional offset circuitry, such as fractional offset circuit 100, provides clarity in resolution through loading a digital driving gate, such as first digital gate 108A, with the tri-state inverter 102. In some implementations, the slope 120 of the input signal waveform at an output of the digital driving gate, such as the first digital gate 108A, is based on the tri-state inverter 102. According to inventive aspects, matching VT-types in the digital driving gate, such as the first digital gate 108A, and in the tri-state inverter 102 enable a single trim of the delay, such as the delay adjustment (td) 104, (e.g., higher resolution) across multiple voltages/temperatures.

FIG. 2A is a block diagram of a fractional offset circuit 200, in accordance with example implementations. FIG. 2B is a graphical representation of delay adjustments (td) 204A, 204B, and 204C of the fractional offset circuit 200, in accordance with certain example implementations. FIG. 2C is a graphical representation of an input signal waveform 206 for the fractional offset circuit 200, in accordance with example implementations. FIG. 2D is a graphical representation of output signals for the fractional offset circuit 200, in accordance with certain example implementations. As illustrated in FIGS. 2A-2D, similar elements to those of FIGS. 1A-1E may not be discussed again for the sake of brevity and conciseness.

As illustrated, in FIGS. 2A-2D, an example fractional offset circuit 200 includes the first digital gate 108A (e.g., a driving gate) and a timing offset circuit portion 238 operably connected to the first digital gate 108A. The timing offset circuit portion 238 includes tri-state inverters 202A, 202B, . . . , 202N, where a capacitive (e.g., MOS capacitance) loading at the node 128 is based on a quantity of enabled tri-state inverters of the tri-state inverters 202A, 202B, . . . , 202N. The capacitive load at the node 128 corresponds to one of slopes 214, 242, or 244 of a waveform 240 (e.g., the input signal waveform 206 with a capacitive load) plotted on a graph of voltage as a function of time. Slope 214 corresponds to a delay adjustment td(1) 204, slope 242 corresponds to a delay adjustment td(2) 246, and slope 244 corresponds to delay adjustment td(3) 248; all being less than a gate delay, such as the gate delay 318 alone and in combination, (e.g., td(1)+td(2)+td(3)<<tgate). The fractional offset circuit 200 further includes the second digital gate 108B, where the timing offset circuit portion 238 is coupled at the node 128 between the first digital gate 108A and the second digital gate 108B, and where the capacitive load (e.g., gate capacitance is slightly more loaded) at the node 128 corresponds to the quantity of enabled tri-state inverters. The quantity of enabled tri-state inverters of the tri-state inverters 202A, 202B, . . . , 202N corresponds to the (e.g., timing) delay adjustment td(1) 204, the delay adjustment td(2) 246, and/or the delay adjustment td(3) 248 of the waveform 240 (e.g., from an input signal, such as the input signal waveform 206). One or more enabled tri-state inverters of the tri-state inverters 202A, 202B, . . . , 202N are configured to control (e.g., adjustment of) a timing delay (duration) of a signal waveform, such as the input signal waveform 206.

As discussed above, there is a desire to add an incremental delay to shift an input signal, such as the input signal waveform 206, an amount that is smaller than a gate delay. This is desirable to allow for incremental trimming of the input signal waveform 206 by a fractional offset, such as one or more of delay adjustments, such as the delay adjustments td(1) 204A, td(2) 204B, and/or td(3) 204C. Often, the output of a pulse generator, such as pulse generator 356, passes through buffers, such as the first digital gate 108A and the second digital gate 108B, as the buffers drive the input signal waveform 206 through several gates (e.g., see FIGS. 3A-3C). Thus, an input signal, such as the input signal waveform 206, is “strengthened” by the first digital gate 108A and the second digital gate 108B.

As illustrated in FIG. 2B, through the timing offset circuit portion 238, a trimmable capacitive load (gate capacitance of enabled tri-state inverters) can be placed on the node 128. In response to each tri-state inverter 202A, 202B, . . . , and 202N being non-enabled, the equivalent gate capacitive load is not connected to the node 128. In response to one or more tri-state inverters, such as the tri-state inverters 202A, 202B, . . . , and/or 202N being enabled, a capacitive load of the enabled tri-state inverters is connected to the node 128 as one or more gate-to-source capacitive loads is now connected to ground. As the capacitive load is no longer floating, voltage from the node 128 charges the capacitive load that results in, for example, one of the slopes 214, 242, or 244 (e.g., that represents a delay to reaching Vth by the second digital gate 108B due to the charging of the capacitive load).

In response to one or more of the tri-state inverter inverters 202A, 202B, . . . , and/or 202N being enabled, the equivalent gate capacitive load is connected to the node 128. The coupling of the equivalent gate capacitive load to the node 128 results in, for example, one or more small delay adjustments, such as the delay adjustments td(1) 204, td(2) 246, td(3) 248, . . . , and/or td(N) (where td(N) corresponds a delay adjustment for tri-state inverter 202N) as one or more capacitive loads is added (e.g., the gate-to-source capacitance (Cgs) ranging from a few femtofarads (fF) to hundreds of femtofarads). One or ordinary skill in the art understands capacitive loads lesser than a few femtofarads and greater than hundreds of femtofarads are fully contemplated without departing from the spirit of the implementation.

As illustrated, according to some implementations, slope 220 of the input signal waveform 206 decreases to the slope 214 in response to one tri-state inverter of the tri-state inverter inverters 202A, 202B, . . . , or 202N being enabled. Also, the slope 220 of the input signal waveform 206 decreases to the slope 242 in response to two tri-state inverters of tri-state inverter inverters 202A, 202B, . . . , or 202N being enabled. Further, the slope 220 of the input signal waveform 206 decreases to the slope 244 in response to three tri-state inverters of tri-state inverter inverters 202A, 202B, . . . , or 202N being enabled. Correspondingly, subsequent slopes would continue to become “smaller” (e.g., having a decreased angle of inclination from horizontal) as more tri-state inverters are enabled and additional capacitive loads are, in turn, added to the node 128. In various examples, depending on a number of enabled tri-state inverters, the slope would be slightly different in comparison to the slope 220 of the input signal waveform 206. As would be appreciated, the difference in the slopes (e.g., the time delay in reaching Vth by the second digital gate 108B) provides for a fractionally trimmed delay allowing for the input signal waveform 206 to be trimmed by a fractional offset. Advantageously, the delay of the input signal waveform 206 may be trimmed with delay adjustments td(1) 204, td(2) 246, td(3) 248, and/or additional delays, such as td(N), not shown that are smaller than a gate delay alone and in combination. In one implementation, up to nine delay adjustments are less than a gate delay as each delay adjustment is approximately ≤⅛th a gate delay; however, one or ordinary skill in the art understands that more delay adjustments of a smaller value can be added without going over a gate delay and departing from the spirit of the implementation. In addition, the load on the node 128 may be based off the number of tri-state inverters that are enabled.

As illustrated in FIG. 2D, dashed line 232 represents the input signal waveform 206 in response to the tri-state inverters 202A, 202B, . . . , and 202N being disabled (e.g., non-enabled); and hence, no capacitive load is provided at the node 128. Dashed line 250 represents delayed input signal waveform 206 in response to a capacitive load of one enabled tri-state inverter of the tri-state inverters 202A, 202B, . . . , or 202N provided at the node 128. The dashed line 250 represents the input signal waveform 206 delayed by delay adjustment td(1) 204. Dashed line 252 represents the delayed input signal waveform 206 in response to a capacitive load of two enabled tri-state inverters of the tri-state inverters 202A, 202B, . . . , or 202N being at the node 128. The dashed line 252 represents the input signal waveform 206 delayed by two delay adjustments (e.g., td(1) 204+td(2) 246). Solid line 234 represents the delayed input signal waveform 206 in response to a capacitive load of three enabled tri-state inverters of the tri-state inverters 202A, 202B, . . . , or 202N at the node 128. The solid line 234 represents the input signal waveform 206 delayed by three delay adjustments (e.g., td(1) 204+td(2) 246+td(3) 248). Thus, a waveform, such as the input signal waveform 206, can be delayed with delays much smaller than a gate delay, such as the gate delay 318, by means of different slopes, such as the slopes 214, 242, and 244.

Advantageously, inventive fractional offset circuit 200 provides clarity in resolution. In certain implementations, a digital driving gate, such as the first digital gate 108A is “loaded” with multiple tri-state inverters, such as the tri-state inverters 202A, 202B, . . . , or 202N, that are included in the fractional offset circuit 200. In some implementations, the slope 220 of the input signal waveform 206 at an output of the digital driving gate is based on a number of enabled (i.e., activated) tri-state inverters, such as the tri-state inverters 202A, 202B, . . . , or 202N. In certain implementations, a relative increase in delay of the input signal waveform 206 is scaled identically (e.g., each slight delay, such as delay adjustments td(1) 204, td(2) 246, td(3) 248, . . . , and/or td(N) increase provided by each tri-state inverter is approximately identical) by selecting matching VT-types (e.g., where VT-type refers to the threshold voltage characteristics associated with different types or categories of transistors) in the digital driving gate and in the tri-state inverters. According to inventive aspects, matching VT-types in the digital driving gate and in the tri-state inverters enable a one or more trims of the delay (e.g., higher resolution) across multiple voltages/temperatures.

FIG. 3A is a block diagram representation of the droop detector circuit 356, in accordance with certain implementations. FIG. 3B is a timing diagram representation of the droop detector circuit 356 as illustrated in FIG. 3A. FIG. 3C is a graphical representation of a simulation output 384 for a droop detector circuit, in accordance with certain implementations.

As illustrated in FIGS. 3A and 3B, the droop detector circuit 356 includes the pulse generator 362, droop sensor 360, and the timing offset circuit portion 238. In a non-limiting example, output clock signal (ck) 364 is operably connected to AND gates 366A, 366B, 366C, 366D, . . . 366(N−1), and 366N. An AND gate is a digital logic gate that performs a logical conjunction operation. An AND gate is a building block of digital circuits and is designed to output a high signal (e.g., represented as “1” or “true”) in response to all input signals being a high digital state (1).

In response to the output clock signal (ck) 364 being at a digital low state (0) for a pre-determined period, outputs o<0>, o<1>, o<2>, o<n−1>, and o<n> of the AND gates 366A, 366B, 366C, 366D, . . . 366 (N−1), and 366N are set to a digital low state (0). The setting to a digital low state (0) of the AND gates 366A, 366B, 366C, 366D, . . . 366 (N−1), and 366N takes one gate delay (e.g., the delay of one AND gate, such as the gate delay 318). Thus, a digital low state (0) from the output clock signal (ck) 364 travels through delay line 368 “quickly” (e.g., in the time of a single gate delay). Continuing with such a non-limiting example, in response to the output clock signal (ck) 364 transitioning from a digital low state (0) to a digital high state (1), the AND gates 366A, 366B, 366C, 366D, . . . 366(N−1), and 366N would transition to the high state (1) value one AND gate after the other. In response to the output clock signal (ck) 364 transitioning from a digital low state (0) to a digital high state (1), after a first delay of first AND gate 366A, output o<0> transitions to a high state (1). After a second delay of second AND GATE 366B, output o<1> transitions to a high state (1) and so on down the delay line 368.

Hence, there is a propagation of the output clock signal (ck) 364 into the delay line 368 in response to the output clock signal (ck) 364 transitioning from a digital low state (0) to a high state (1) and flip-flops 370A, 370B, 370C, . . . 370(N−1), and 370N capture where the transition from digital low state (0) to the digital high state (1) is at upon the rising edge of clock input signal (ckin) 372. Continuing with such a non-limiting example, in response to the transition from the digital low state (0) to the digital high state (1) moving through 4 AND gates 366A, 366B, 366C, 366D as the rising edge of the clock input signal (ckin) 372 is received by the AND gates 366A, 366B, 366C, and 366D, the four outputs o<0>, o<1>, o<2>, o<3> that transitioned from the digital low state (0) to the digital high state (1) are captured by the AND gates 366A, 366B, 366C, and 366D and the other outputs remain at a digital low state (0) (i.e., as the transition from the digital low state (0) to the digital high state (1) are not captured by the remaining AND gates, such as AND gates 366 (N−1) and 366N, before the rising edge of the clock input signal (ckin) 372).

In some cases, to have the output clock signal (ck) 364 transition to a digital low state (0) and then transition back to a high state (1) and stay at a high state (1) until the next rising edge of the clock input signal (ckin) 372 is desirable. The longer the output clock signal (ck) 364 remains at a digital high state (1), the longer measurement window (t₁) 382 and the greater quantity of AND gates 366 the high state (1) passes through before the next rising edge of the clock input signal (ckin) 372. In response, delay line output 374 represents a number of AND gates that transition from digital low state (0) to a high state (1) before the rising edge of the input clock signal (ckin) 364. During output clock signal (ck) pulse width 376 the delay line output 374 is zero (e.g., a digital low state). In response to the transition from digital low state (0) to the digital high state (1) of the output clock signal (ck) 364, the high state (1) moves through one, two, three and four AND gates. Next, at the rising edge of the clock input signal (ckin) 372, the flip-flops 370A, 370B, 370C, . . . 370(N−1), and 370N are configured to capture the input and output(s) a thermometer code 378 that in this non-limiting example is four. Thermometer coded output 378 represents the number of AND gates that transition from digital low state (0) to digital high state (1) that the output clock signal (ck) 364 was able to move “through” (e.g., transition the AND gates from a digital low state (0) to a digital high state (1)) before the rising edge of the clock input signal (ckin) 372.

In certain aspects, on next ckin period 380 the process repeats. So, the rising edge of the clock input signal (ckin) 372 triggers the output clock signal (ck) pulse width 376 that transitions the AND gates 366A, 366B, 366C, 366D, . . . 366(N−1), and 366N down to a digital low state (0). The output clock signal (ck) pulse width 376 resets the delay line 368. Then in response to the transition from digital low state (0) to a high state (1) of the output clock signal (ck) 364, the high state (1) propagates through the delay line 368 and at the rising edge of the clock input signal (ckin) 372 thermometer coded output(s) 378 is captured. In some implementations, there is a desire to be able to trim clock signal (ck) pulse width 376 so that the output clock signal (ck) 364 can move “through” (e.g., propagating from an input to an output) each AND gate 366A, 366B, 366C, 366D, . . . 366 (N−1), and 366N.

The measurement window (t₁) 382 represents a timing window to allow the propagation of the transition from digital low state (0) to digital high state (1) of the output clock signal (ck) 364 into the delay line 368. So, the smaller the measurement window (t₁) 382, the lower the number of AND gates 366 the high state (1) transitions “through.” In some cases, there is a desire to be able to trim the measurement window (t₁) 382 to travel through a pre-determined amount of AND gates from the AND gates 366A, 366B, 366C, 366D, . . . 366 (N−1), and 366N. This is desirable for calibration purposes or to modify the sensitivity of the droop sensor 360. In some implementations, the measurement window (t₁) 382 is useable to calibrate the droop sensor 360. In some implementations, the measurement window (t₁) 382 is trimmed to allow the output clock signal (ck) 364 to transition through a number of AND gates based upon the resolution desired (e.g., predetermined) for the droop sensor 360.

As illustrated in FIGS. 3A-3C, the droop detector circuit 356, through the droop sensor 360, is measuring voltage variation by means of timing variation. In response to voltage 386 decreasing or drooping, the timing of one gate delay increases. Since the timing of one gate delay increases (as timing to gate Vth increases as discussed above) and the measurement window (t₁) stays constant, then droop sensor 360 is outputting the thermometer code 378 that is smaller (e.g., less robust, or having less resolution) since voltage 386 is powering fewer of The AND gates 366A, 366B, 366C, 366D, . . . 366 (N−1), and 366N in the same period.

As illustrated in FIG. 3C, simulation 384 shows sensor 360 reading 29 gates at Vmax of V(v) 386 (e.g., 1V). As voltage V(v) 386 decreases and in response to the voltage hitting point 388, sensor 360 goes from 29 to 28 gates. This is due to delay elements (e.g., The AND gates 366A, 366B, 366C, 366D, . . . 366 (N−1), and 366N) in the delay line 368 being passed through by the voltage V(v) 386 that is decreasing by approximately 2% though each delay element. In addition, such a decrease in voltage V(v) 386 by approximately 2% would cause the delays to get “longer and longer” as each delay takes longer to get to Vth. Since the measurement window (t₁) 382 remains the same and the delay is getting longer and longer, sensor 360 measures “less and less” elements as voltage 386 is decreasing.

In other implementations, the resolution of the difference in voltage that is measurable is one LSB (least significant bit) or one gate. The voltage for one LSB is 2% of Vdd. Hence, what is measurable by means of code variation is by steps of 2% of Vdd and this precision is one gate delay.

To increase precision and resolution, a timing offset that is smaller than a gate delay, is generated by the timing offset circuit portion 238. Continuing with such a non-limiting example of FIG. 3C, each gate delay takes, for example, approximately 12 ps. By enabling one of the tri-state inverters 202A, 202B, . . . , or 202N, this time is reduced by approximately 1 ps. Through enabling one or more of the tri-state inverters 202A, 202B, . . . , 202N, the measurement window (t₁) 382 can be moved (i.e., shifted) by ⅛th of a gate delay.

As illustrated in FIG. 3C, continuing with such a non-limiting example, each successive enabled tri-state inverter indicated by reference numerals 392(1), 392(2), 392(3), 392(4), 392(5), 392(6), and 392(7), respectively, produces an incremental delay portion (e.g., step) 316 corresponding to a delay adjustment (td), such as the delay adjustments (td) 104, 204, 246, or 248. In the non-limiting example, there are seven tri-state inverters represented as 392(1), 392(2), 392(3), 392(4), 392(5), 392(6), and 392(7). One of ordinary skill in the art understands more tri-state inverters can be added to fractional offset circuit 238 without departing from the spirit of the implementation. In response to a first enabled tri-state inverter, represented as 392(1), being connected to the node 128, 28-code 394 shifts a small amount to the left equal to incremental delay portion (e.g., step) 316. Therefore, by enabling just one tri-state inverter is equivalent to moving the threshold voltage (Vth) by few millivolts, corresponding to A, on voltage V(v) 386 (e.g., 1.8 millivolts). Thus, advantageously, fractional offset circuit 238 is able to trim code 394 by 1.8 millivolts corresponding to a resolution of 0.2% (in contrast to 2% of certain aspects, and would be much smaller than the resolution to switch from one code to another (e.g., from 28-code to 27-code in the thermometer code output) corresponding to the gate delay 318).

While the discussion of FIGS. 3A to 3C are discussed with example detailed fractional offset circuit 238 being used with the droop sensor 360, one or ordinary skill in the art understands fractional offset circuit 238 is able to be used with a digital PLL (phase lock loop that compares the phase difference between the input and output signals to generate an error signal, indicating the phase difference between the two), a digital ADC (analog-to-digital converter for quantization and encoding), or the like without departing from the spirit of the implementation.

Schemes and techniques relate to the capacity to provide clarity in resolution for a voltage droop detector, such as droop detector 356. Advantageously, fractional offset circuitry 238 provides such clarity in resolution. In certain implementations, the digital gate 108A is “loaded” with multiple tri-state inverters, such as tri-state inverters 202A, 202B, . . . , and 202N, that are included in the fractional offset circuit 238. In certain implementations, the portions 316 in delay of the input signal waveform is scaled identically (e.g., each slight delay increase provided by each tri-state inverter is approximately identical) by selecting matching VT-types (e.g., where VT-type refers to the threshold voltage characteristics associated with different types or categories of transistors) in the digital gate 108A and in the tri-state inverters, such as tri-state inverters 202A, 202B, . . . , and 202N. According to inventive aspects, matching VT-types in the digital gate 108A and in the tri-state inverters, such as tri-state inverters 202A, 202B, . . . , and 202N, enable one or more trimmable delays (e.g., higher resolution) across multiple voltages/temperatures.

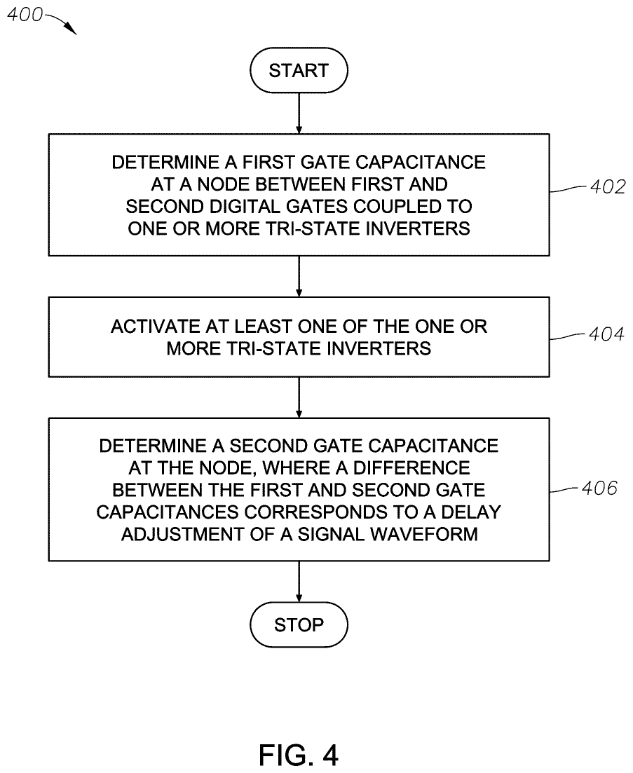

FIG. 4 illustrates an example method 400 for an example fractional offset of an input signal, in accordance with certain implementations. Advantageously, in various implementations, the method 400 may determine a delay adjustment of a signal waveform based on gate capacitance at a node. The method 400 may be implemented with reference to circuit implementations as shown in FIGS. 1A, 2A, and 3A.

While FIG. 4 shows a sequence of steps in procedure 400, one of ordinary skill in the art understands that any order of sequences is possible without departing from the implementation. The sequence shown for method 400 may be implemented with FIGS. 1A, 2A, 3, and 5.

In step 402 of method 400 for an example fractional offset of an input signal, a first gate capacitance, at a node between a first digital gate and a second digital gate coupled to one or more tri-state inverters, is determined. For instance, with reference to various implementations as described in FIGS. 2A-2D, a gate capacitance, resulting from one or more enabled tri-state inverters, such as tri-state inverters 202A, 202B, . . . , and/or 202N, at node 128, between first digital gate 108A and second digital gate 108B, is determined. Process flows from step 404 to step 406.

In step 404 of method 400, at least one of one or more tri-state inverters is activated. For instance, with reference to various implementations as described in FIGS. 2A-2D, at least one of the one or more tri-state inverters, such as tri-state inverters 202A, 202B, . . . , and/or 202N, are activated with one or more of control signals enl<0>, enl<1>, . . . , and/or enl<n>. Process flows from step 404 to step 406.

In step 406 of method 400, a second gate capacitance at the node is determined, where a difference between the first and the second gate capacitances corresponds to delay adjustment of a signal waveform. For instance, with reference to various implementations as described in FIGS. 2A-2D, a second gate capacitance at the node 128 is determined, where the difference between the first and the second gate capacitances (e.g., fine tuning the node capacitance) corresponds to a delay adjustment, such as delay adjustment td, such as delay adjustment td(1) 204, td(2) 246, td(3) 248, . . . , and/or td(N), of a signal waveform, such as the input signal waveform 206. The delay adjustment (td) results in delayed input signal waveform represented by dashed line 250 (e.g., a single delay adjustment (td)), dashed line 252 (e.g., two delay adjustments (2×td)), and solid line 234 (e.g., three delay adjustments (3×td)). Optionally, process flows from step 406 to step 408 (not shown).

In step 408, a delay offset of the signal waveform is controlled with a quantity of enabled tri-state inverters and the delay adjustment corresponds to a change in a slope of the signal waveform plotted on a graph of voltage as a function of time. For instance, with reference to various implementations as described in FIGS. 2A-2D, a delay offset, such as delay adjustment td(1) 204, td(2) 246, td(3) 248, . . . , and/or td(N), of the input signal waveform 206 is controlled with a quantity of enabled tri-state inverters, such as tri-state inverters 202A, 202B, . . . , and/or 202N, and the delay adjustment corresponds to a change in a slope, such as slopes 214, 242, and/or 244, of the input signal waveform 206 plotted on a graph of voltage as a function of time.

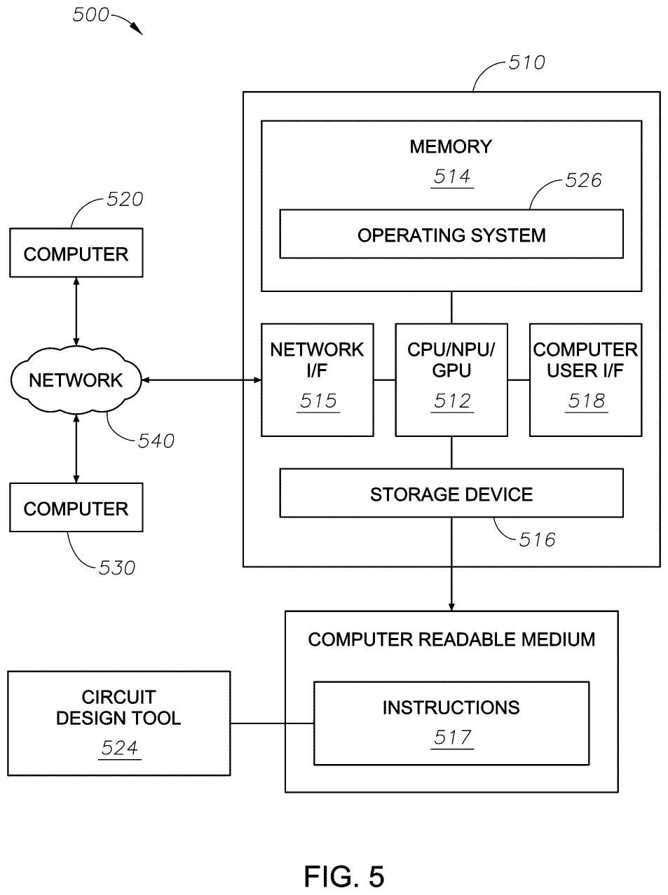

FIG. 5 illustrates example hardware components in the computer system 500 that may be used to control capacitance at a node coupled to a driving digital gate though enablement of one or more tri-state inverters, where a capacitive load at the node delays a signal waveform by a delay adjustment based on the capacitive load. In certain implementations, the example computer system 500 (e.g., networked computer system and/or server) may include circuit design tool 524 and execute software based on the procedure as described with reference to method 400 in FIG. 4. In certain implementations, the circuit design tool 524 may be included as a feature of an existing compiler software program allowing users to input various data including but not limited to: data related to a selection of a quantity of enabled tri-state inverters and voltage threshold (VT)-types.

The circuit design tool 524 may provide generated computer-aided physical layout designs for fractional offset circuits. The method 400 may be stored as program code as instructions 517 in the computer readable medium of the storage device 516 (or alternatively, in memory 514) that may be executed by the computer 510, or networked computers 520, 530, other networked electronic devices (not shown) or a combination thereof. In certain implementations, each of the computers 510, 520, 530 may be any type of computer, computer system, or other programmable electronic device. Further, each of the computers 510, 520, 530 may be implemented using one or more networked computers, e.g., in a cluster or other distributed computing system.

In certain implementations, the system 500 may be used with semiconductor integrated circuit (IC) designs that contain all standard cells, all blocks or a mixture of standard cells and blocks. In a particular example implementation, the system 500 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 500 may be stored in one or more of memory 514 or storage devices 516 of computer 510 or in networked computers 520, 530.

The system 500 may perform the following functions automatically, with variable user input: determination of read current requirements/thresholds, determination of leakage current requirements/thresholds, identification of logic designs (i.e., periphery circuit designs (i.e., logic threshold voltages, threshold voltage implant layers)), determination of a desired threshold voltage-combination, determination of minimum voltage assist requirements, identification of bit-cell types, determination of memory specific optimization modes (memory optimization mode), floor-planning, including generation of cell regions sufficient to place all standard cells; standard cell placement; power and ground net routing; global routing; detail routing and pad routing. In some instances, such functions may be performed substantially via user input control. Additionally, such functions can be used in conjunction with the manual capabilities of the system 500 to produce the target results that are required by a designer. In certain implementations, the system 500 may also provide for the capability to manually perform functions such as: cell region creation, block placement, pad, and cell placement (before and after automatic placement), net routing before and after automatic routing and layout editing. Moreover, verification functions included in the system 500 may be used to determine the integrity of a design after, for example, manual editing, design rule checking (DRC) and layout versus schematic comparison (LVS).

In one implementation, the computer 510 includes a central processing unit (CPU) 512 having at least one hardware-based processor coupled to a memory 514. The memory 514 may represent random access memory (RAM) devices of main storage of the computer 510, supplemental levels of memory (e.g., cache memories, non-volatile or backup memories (e.g., programmable or flash memories)), read-only memories, or combinations thereof. In addition to the memory 514, the computer system 500 may include other memory located elsewhere in the computer 510, such as cache memory in the CPU 512, as well as any storage capacity used as a virtual memory (e.g., as stored on a storage device 516 or on another computer coupled to the computer 510).

The computer 510 may further be configured to communicate information externally. To interface with a user or operator (e.g., a circuit design engineer), the computer 510 may include a user interface (I/F) 518 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 510 may include a network interface (I/F) 515 which may be coupled to one or more networks 540 (e.g., a wireless network) to enable communication of information with other computers and electronic devices. The computer 510 may include analog and/or digital interfaces between the CPU 512 and each of the components 514, 515, 516, and 518. Further, other non-limiting hardware environments may be used within the context of example implementations.

The computer 510 may operate under the control of an operating system 526 and may execute or otherwise rely upon various computer software applications, components, programs, objects, modules, data structures, etc. (such as the programs associated with the method 400 and related software). The operating system 526 may be stored in the memory 514. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 526 in the example of FIG. 5 is shown in the memory 514, but components of the aforementioned software may also, or in addition, be stored at non-volatile memory (e.g., on storage device 516 (data storage) and/or the non-volatile memory (not shown). Moreover, various applications, components, programs, objects, modules, and the like may also execute on one or more processors in another computer coupled to the computer 510 via the network 540 (e.g., in a distributed or client-server computing environment) where the processing to implement the functions of a computer program may be allocated to multiple computers 520, 530 over the network 540.

In example implementations, circuit macro diagrams have been provided in FIGS. 1-3, whose redundant description has not been duplicated in the related description of analogous circuit macro diagrams. It is expressly incorporated that the same cell layout diagrams with identical symbols and/or reference numerals are included in each of embodiments based on its corresponding figure(s).

Although one or more of FIGS. 1-5 may illustrate systems, apparatuses, or methods according to the teachings of the disclosure, the disclosure is not limited to these illustrated systems, apparatuses, or methods. One or more functions or components of any of FIGS. 1-5 as illustrated or described herein may be combined with one or more other portions of another of FIGS. 1-5. Accordingly, no single implementation described herein should be construed as limiting and implementations of the disclosure may be suitably combined without departing from the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 514, the storage device 516, or both, may include tangible, non-transitory computer-readable media, or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus, or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

The subject matter of the claims is not limited to the implementations and illustrations provided herein, the intention is that modified forms of those implementations including portions of implementations and combinations of elements of different implementations be in accordance with the claims. In the development of any such implementation, there is an appreciation as in any engineering or design project, that numerous implementation-specific decisions are made to achieve the developers' specific goals, such as compliance with system-related and business-related constraints that vary from one implementation to another. Moreover, while such a development effort is complex and time consuming, there is an appreciation for those of ordinary skill having benefit of this embodiments the development would nevertheless be a routine undertaking of design, fabrication, and manufacture.

Reference has been made in detail to various implementations, examples of that are illustrated in the accompanying drawings and figures. In the above description, numerous specific details are set forth to provide a thorough understanding of the various implementations provided herein. However, the embodiments provided herein can be practiced without these specific details. In some other instances, well-known methods, procedures, components, circuits, and networks have not been described in detail so as not to unnecessarily obscure details of the various implementations.

Although the terms first, second, and the like are used herein to describe various elements, these elements should not be limited by these terms. These terms are used to distinguish one element from another. For example, a first element can be termed a second element, and, similarly, a second element is able to be termed a first element. The first element and the second element are both elements, respectively, but they are not to be considered the same element.

The terminology used in the description of the various implementations provided herein is for the purpose of describing implementations and is not intended to limit the embodiments provided herein. As used in the description of the various implementations provided herein and appended claims, the singular forms “a,” “an,” and “the” are intended to include the plural forms as well, unless the context clearly indicates otherwise. The term “and/or” as used herein refers to and encompasses all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down;” “upper” and “lower;” “upwardly” and “downwardly;” “below” and “above;” and other similar terms indicating relative positions above or below a given point or element are used in connection with some implementations of various technologies described herein.

While the foregoing is directed to implementations of various techniques described herein, other, and further implementations can be devised in accordance with the embodiments herein that may be determined by the claims that follow.

Although the subject matter has been described in language specific to structural features and/or methodological acts, the subject matter defined in the appended claims is not necessarily limited to the specific features or acts described above. Rather, the specific features and acts described above are disclosed as example forms of implementing the claims.

What is claimed is:

1. A circuit comprising:
one or more tri-state inverters, wherein each enabled tri-state inverter of the one or more tri-state inverters is configured to provide a respective delay adjustment of a signal waveform.

2. The circuit of claim 1, wherein:
the respective delay adjustment corresponds to a duration less than a gate delay, and
the gate delay corresponds to a propagation delay of a logic gate.

3. The circuit of claim 1, wherein the respective delay adjustment corresponds to a change in a slope of the signal waveform plotted on a graph of voltage as a function of time.

4. The circuit of claim 1, wherein enabled tri-state inverters of the one or more tri-state inverters are configured to provide a plurality of delay adjustments of the signal waveform.

5. The circuit of claim 4, wherein:
the plurality of delay adjustments includes one or more incremental portions of durations less than a gate delay; and
each delay adjustment of the plurality of delay adjustments corresponds to a different slope of the signal waveform plotted on a graph of voltage as a function of time.

6. The circuit of claim 1, wherein:
a first enabled tri-state inverter of the one or more tri-state inverters is configured to provide a first respective delay adjustment of the signal waveform; and
a difference between the first delay adjustment and the signal waveform corresponds to a difference between a slope of the first enabled tri-state inverter and the slope of the signal waveform plotted on a graph of voltage as a function of time.

7. The circuit of claim 1, wherein:
first and second enabled tri-state inverters of the enabled tri-state inverters are configured to provide respective first and second respective delay adjustments of the signal waveform; and
a difference between the first and second delay adjustments corresponds to a difference between respective first and second slopes of the signal waveform plotted on a graph of voltage as a function of time.

8. The circuit of claim 1, wherein each of the one or more tri-state inverters is coupled in parallel.

9. The circuit of claim 1, wherein each tri-state inverter of the one or more tri-state inverters comprises:
a pair of NMOS transistors;
a pair of PMOS transistors; and
an inverter.

10. The circuit of claim 1, wherein a tri-state inverter is enabled upon enabling at least one PMOS transistor and enabling at least one NMOS transistor.

11. The circuit of claim 1, further comprising:
first and second digital gates, wherein:
a node is coupled between the first and second digital gates;
the node is coupled to the one or more tri-state inverters; and
at least the first digital gate includes a same voltage-threshold type as the one or more tri-sate inverters.

12. The circuit of claim 11, wherein a capacitance at the node corresponds to the respective delay adjustment.

13. The circuit of claim 1, wherein each additional enabled tri-state inverter of the one or more tri-state inverters is configured to generate a respective incremental delay adjustment to the signal waveform.

14. A method comprising:
determining a first gate capacitance at a node between first and second digital gates coupled to one or more tri-state inverters;
activating at least one of the one or more tri-state inverters; and
determining a second gate capacitance at the node, wherein a difference between first and second gate capacitances corresponds to a delay adjustment of a signal waveform.

15. The method of claim 14, wherein:
a quantity of enabled tri-state inverters is configured to control a delay offset of the signal waveform; and
the delay adjustment corresponds to a change in a slope of the signal waveform plotted on a graph of voltage as a function of time.

16. A circuit comprising:
a first digital gate; and
a timing offset circuit portion coupled to the first digital gate, including: one or more tri-state inverters, wherein a capacitance at an output of the first digital gate is based on a quantity of enabled tri-state inverters of the one or more tri-state inverters.

17. The circuit of claim 16, wherein:
the capacitance at the output of the first digital gate corresponds to a slope of a waveform plotted on a graph of voltage as a function of time; and
the slope corresponds to a duration less than a gate delay.

18. The circuit of claim 16, further comprising:
a second digital gate, wherein the timing offset circuit portion is coupled at a node between the first and second digital gates, and wherein the capacitance at the node corresponds to the quantity of the enabled tri-state inverters.

19. The circuit of claim 16, wherein the quantity of the enabled tri-state inverters of the one or more tri-state inverters correspond to a delay adjustment of a signal waveform.

20. The circuit of claim 16, wherein one or more enabled tri-state inverters of the one or more tri-state inverters are configured to control a timing delay of a signal waveform.
